(19) United States
(12) Patent Application Publication
(10) Pub. No.: US 2019/0267261 A1
(43) Pub. Date: Aug. 29, 2019

(54) LIGHT IRRADIATION TYPE HEAT TREATMENT METHOD AND HEAT TREATMENT APPARATUS

(71) Applicant: SCREEN HOLDINGS CO., LTD., Kyoto (JP)

(72) Inventors: Katsuichi Akiyoshi, Kyoto (JP); Mao OMORI, Kyoto (JP); Shinichi IKEDA, Kyoto (JP)

(21) Appl. No.: 16/221,112

(22) Filed: Dec. 14, 2018

(30) Foreign Application Priority Data
Feb. 28, 2018 (JP) 2018-035062

(51) Int. Cl. H01L 21/67

(52) U.S. Cl. CPC H01L 21/67115; H01L 21/67248; G01N 25/72; H01L 21/6719; H01L 21/67288

(57) ABSTRACT

A semiconductor wafer is preheated by halogen lamps; thereafter, the semiconductor wafer is heated by irradiation with flash of light from flash lamps. A radiation thermometer measures the temperature of the back surface of the semiconductor wafer at predetermined sampling intervals and acquires a plurality of temperature measurement values. Of the plurality of temperature measurement values, a temperature integrated value is calculated by integrating a set number of the temperature measurement values acquired from the start point of integration after a start time of irradiation of the flash light. When the calculated temperature integrated value falls out of the range between the upper limit value and the lower limit value, the semiconductor wafer is determined to be broken at the time of flash light irradiation.

### BACKGROUND OF THE INVENTION

### Field of the Invention

The present invention relates to a heat treatment apparatus and a heat treatment method which irradiate a thin plate-like precision electronic substrate (hereinafter referred to simply as a “substrate”) such as a semiconductor wafer with light to heat the substrate.

### Description of the Background Art

In the process of manufacturing a semiconductor device, impurity doping is an essential step for forming a pn junction in a semiconductor wafer. At present, it is common practice to perform impurity doping by an ion implantation process and a subsequent annealing process. The ion implantation process is a technique for causing ions of impurity elements such as boron (B), arsenic (As) and phosphorus (P) to collide against the semiconductor wafer with high acceleration voltage, thereby physically implanting the impurities into the semiconductor wafer. The implanted impurities are activated by the subsequent annealing process. When annealing time in this annealing process is approximately several seconds or longer, the implanted impurities are deeply diffused by heat. This results in a junction depth much greater than a required depth, which might constitute a hindrance to good device formation.

In recent years, attention has been given to flash lamp annealing (FLA) that is an annealing technique for heating a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer implanted with impurities in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer. Therefore, the temperature rise in an extremely short time with the xenon flash lamps allows only the activation of impurities to be achieved without deep diffusion of the impurities.

In the heat treatment apparatus using such flash lamps, the front surface of the semiconductor wafer is instantaneously irradiated with flashes of light having extremely high energy; therefore, the front surface temperature of the semiconductor wafer rapidly rises, while the back surface temperature does not rise so much. For this reason, abrupt thermal expansion occurs only on the front surface of the semiconductor wafer, and the semiconductor wafer is deformed such that the upper surface thereof is warped to be convex. And at the next moment, the semiconductor wafer was deformed such that the lower surface thereof is warped to be convex due to recoil.

When the semiconductor wafer is deformed such that the upper surface thereof to be convex, the edge of the wafer collides with the susceptor. Conversely, when the semiconductor wafer is deformed such that the lower surface thereof is convex, the middle part of the wafer collides with the susceptor. As a result, there has been a problem that the semiconductor wafer is broken due to the impact of collision with the susceptor.

When wafer breakage occurs during flash heating, it is necessary to quickly detect the breakage and to stop the introduction of the succeeding semiconductor wafer and to clean the inside of the chamber. Also, from the viewpoint of preventing adverse effects such as particles generated due to wafer breakage scattering outside the chamber and adhering to the subsequent semiconductor wafer, it is preferable that breakage of the wafer is detected inside of the chamber before opening a carry-in/carry-out port of the chamber immediately after the flash heating.

For this reason, in Japanese Patent Application Laid-Open No. 2009-231697, for example, a technique in which a microphone is provided in a chamber, in which flash heating treatment is performed, to detect a sound when the semiconductor wafer breaks, thereby determining the wafer breakage is disclosed. Also, in Japanese Patent Application Laid-Open No. 2015-130423, a technique in which reflected light from the semiconductor wafer is received by a light guiding rod and wafer breakage is detected from the intensity of the reflected light is disclosed.

However, the technique disclosed in Japanese Patent Application Laid-Open No. 2009-231697 has involved a difficulty in filtering for extraction of only a breaking sound of the semiconductor wafer. Also, in the technique disclosed in Japanese Patent Application Laid-Open No. 2015-130423, a step of rotating the light guide rod is required twice before and after the flash light irradiation, therefore, the throughput is deteriorated.

### SUMMARY OF THE INVENTION

The present invention is intended for a heat treatment method for heating a substrate by irradiating the substrate with a flash of light.

According to one aspect of the present invention, the heat treatment method includes the steps of (a) heating the substrate to a preheating temperature by irradiating with light from continuous lighting lamps, (b) irradiating a front surface of said substrate with the flash light from a flash lamp, (c) acquiring a plurality of temperature measurement values by measuring temperatures of said substrate at predetermined sampling intervals, (d) of said plurality of temperature measurement values, calculating a temperature integrated value by integrating a set number of the temperature measurement values acquired from a start point of integration after a start time of irradiation of said flash light, and (e) determining breakage of said substrate based on said temperature integrated value.

The breakage of the substrate at the time of flash light irradiation can be detected with a simple configuration.

The present invention is also intended for a heat treatment apparatus for heating a substrate by irradiating the substrate with a flash of light.

According to one aspect of the present invention, the heat treatment apparatus includes a chamber for receiving a substrate therein, a susceptor for holding the substrate in said chamber, continuous lighting lamps for heating said substrate to a preheating temperature by irradiating said substrate held by said susceptor with light, a flash lamp for irradiating a front surface of said substrate with the flash light, a radiation thermometer for acquiring a plurality of temperature measurement values by measuring temperatures of said substrate at predetermined sampling intervals, an integrator for, of said plurality of temperature measurement values, calculating a temperature integrated value by integrating a set number of the temperature measurement values acquired from the start point of integration after a start time of irradiation of said flash light, and a determiner for determining breakage of said substrate based on said temperature integrated value.

The breakage of the substrate at the time of flash light irradiation can be detected with a simple configuration.

Therefore, the breakage of the substrate at the time of flash light irradiation can be detected with a simple configuration.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view showing an arrangement of halogen lamps;

FIG. 8 is a block diagram showing functions of a radiation thermometer and a controller;

FIG. 9 is a flowchart showing a treatment procedure of the semiconductor wafer,

FIG. 10 is a graph showing changes of the back surface temperature of the semiconductor wafer measured by the radiation thermometer; and

FIG. 11 is a diagram showing an example of a setting screen of an upper limit and a lower limit.

### DESCRIPTION OF THE PREFERRED EMBODIMENTS

A preferred embodiment according to the present invention will now be described in detail with reference to the drawings.

### First Embodiment

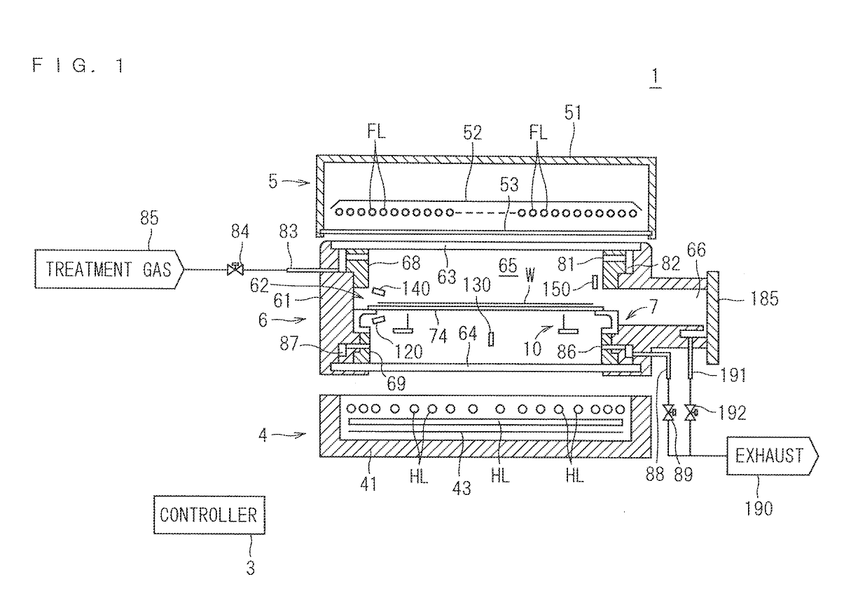

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W serving as a substrate with flashes of light to heat the semiconductor wafer W. The size of the semiconductor wafer W to be treated is not particularly limited. For example, the semiconductor wafer W to be treated has a diameter of 300 mm and 450 mm (in the present embodiment, a diameter of 300 mm is adopted). The semiconductor wafer W prior to the transport into the heat treatment apparatus 1 is implanted with impurities. The heat treatment apparatus 1 performs a heating treatment on the semiconductor wafer W to thereby activate the impurities implanted in the semiconductor wafer W. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and a halogen heating part 4 including a plurality of built-in halogen lamps HL. The flash heating part 5 is provided over the chamber 6, and the halogen heating part 4 is provided under the chamber 6. Also, the heat treatment apparatus 1 includes a holder 7 for holding the semiconductor wafer W in a horizontal attitude inside the chamber 6 and a transfer mechanism 10 for transferring the semiconductor wafer W between the holding section 7 and the outside of the apparatus. The heat treatment apparatus 1 further includes a controller 3 for controlling operating mechanisms provided in the halogen heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the halogen heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is inserted at some midpoint in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is inserted at some midpoint in the gas supply pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits.

A gas exhaust pipe 191 for exhausting the gas from the heat treatment space 65 is also connected to a distal end of the transport opening 66. The gas exhaust pipe 191 is connected through a valve 192 to the exhaust part 190. By opening the valve 192, the gas in the chamber 6 is exhausted through the transport opening 66.

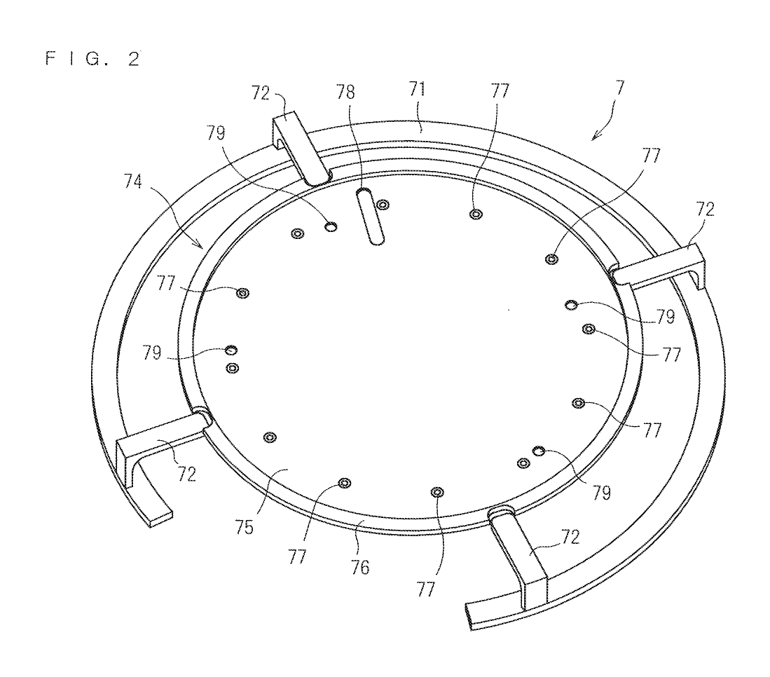

FIG. 2 is a perspective view showing the entire external appearance of the holder 7. The holder 7 includes a base ring 71, coupling portions 72, and a susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1).

The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

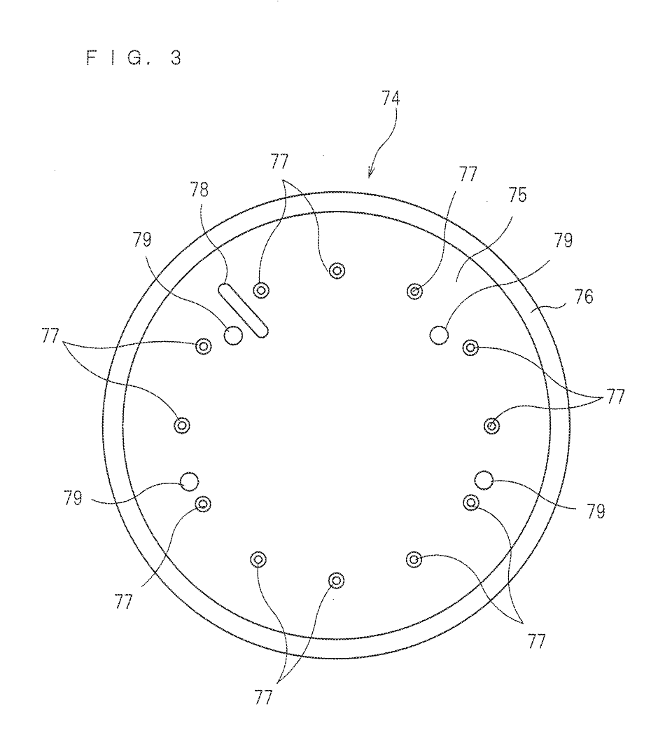

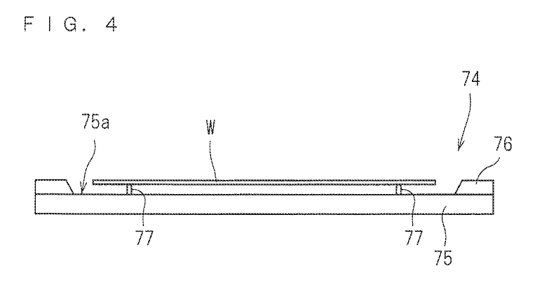

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the twelve substrate support pins 77 have respective upper end portions coming in contact with the lower surface of the semiconductor wafer W to support the semiconductor wafer W. The semiconductor wafer W is supported in a horizontal attitude by the twelve substrate support pins 77 because the twelve substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for a radiation thermometer 120 (with reference to FIG. 1) to receive radiation (infrared radiation) emitted from the lower surface of the semiconductor wafer W. Specifically, the radiation thermometer 120 receives the radiation emitted from the lower surface of the semiconductor wafer W through the opening 78, and measures the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

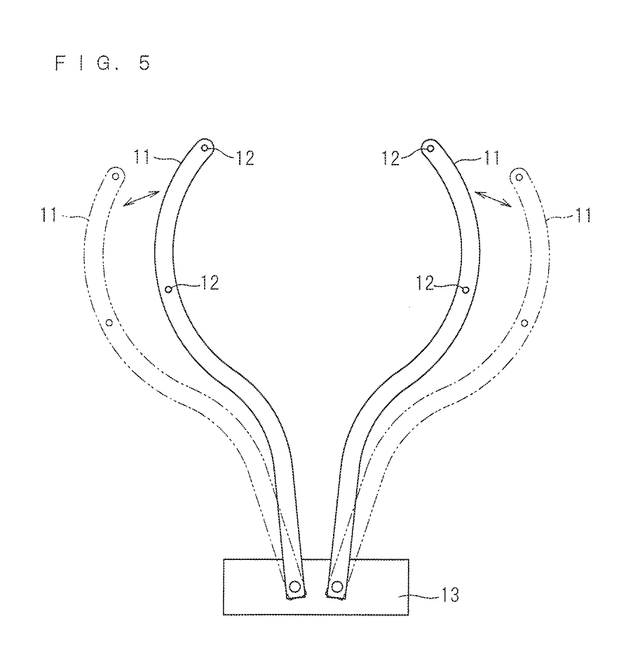

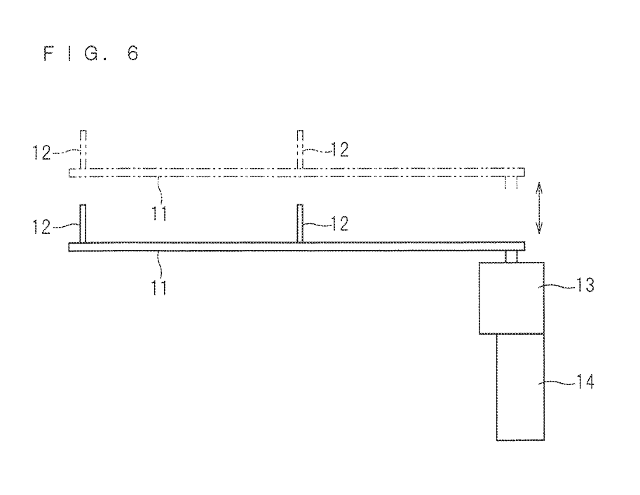

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

As shown in FIG. 1, the heat treatment apparatus 1 is provided with three radiation thermometers 120, 130, and 140. As mentioned above, the radiation thermometer 120 measures the lower surface of the temperature of the semiconductor wafer W through the opening 78 provided in the susceptor 74. The radiation thermometer 130 senses infrared radiation emitted from the middle part of the susceptor 74 to measure the temperature of the middle part. The radiation thermometer 140 senses infrared radiation emitted from the upper surface of the semiconductor wafer W to measure the temperature of the upper surface of the wafer. As the radiation thermometer 140, a high-speed radiation thermometer capable of following sharp temperature change on the upper surface of the semiconductor wafer W at the instant when flash of light from the flash lump FL are irradiated thereon is preferably employed. Further, the heat treatment apparatus 1 is provided with a temperature sensor 150 as well. The temperature sensor 150 measures an ambient temperature of the heat treatment space 65 in the chamber 6.

The flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 and the upper chamber window 63 are opposite to each other. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane.

Each of the xenon flash lamps FL includes a rod-shaped glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp HL because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The halogen heating part 4 provided under the chamber 6 includes an enclosure 41 incorporating the multiple (in the present preferred embodiment, 40) halogen lamps HL. The halogen heating part 4 directs light from under the chamber 6 through the lower chamber window 64 toward the heat treatment space 65 to heat the semiconductor wafer W by means of the halogen lamps HL.

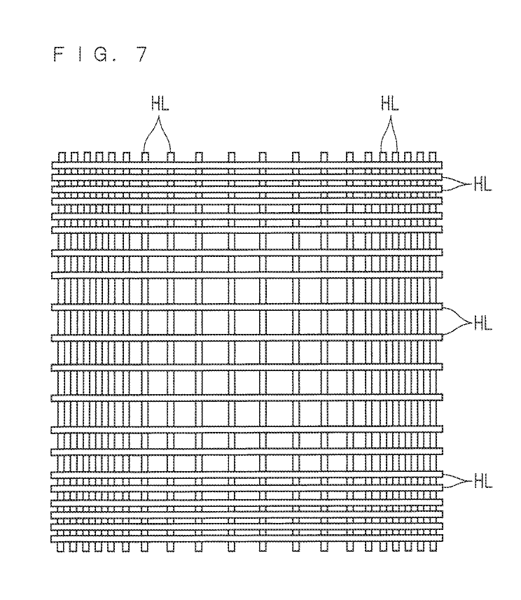

FIG. 7 is a plan view showing an arrangement of the multiple halogen lamps HL. The 40 halogen lamps HL are arranged in two tiers, i.e. upper and lower tiers. That is, 20 halogen lamps HL are arranged in the upper tier closer to the holder 7, and 20 halogen lamps HL are arranged in the lower tier farther from the holder 7 than the upper tier. Each of the halogen lamps HL is a rod-shaped lamp having an elongated cylindrical shape.

The 20 halogen lamps HL in each of the upper and lower tiers are arranged so that the longitudinal directions thereof are in parallel with each other along a main surface of a semiconductor wafer W held by the holder 7 (that is, in a horizontal direction). Thus, a plane defined by the arrangement of the halogen lamps HL in each of the upper and lower tiers is also a horizontal plane.

As shown in FIG. 7, the halogen lamps HL in each of the upper and lower tiers are disposed at a higher density in a region opposed to the peripheral portion of the semiconductor wafer W held by the holder 7 than in a region opposed to the central portion thereof. In other words, the halogen lamps HL in each of the upper and lower tiers are arranged at shorter intervals in the peripheral portion of the lamp arrangement than in the central portion thereof. This allows a greater amount of light to impinge upon the peripheral portion of the semiconductor wafer W where a temperature decrease is prone to occur when the semiconductor wafer W is heated by the irradiation thereof with light from the halogen heating part 4.

The group of halogen lamps HL in the upper tier and the group of halogen lamps HL in the lower tier are arranged to intersect each other in a lattice pattern. In other words, the 40 halogen lamps HL in total are disposed so that the longitudinal direction of the 20 halogen lamps HL arranged in the upper tier and the longitudinal direction of the 20 halogen lamps HL arranged in the lower tier are orthogonal to each other.

Each of the halogen lamps HL is a filament-type light source which passes current through a filament disposed in a glass tube to make the filament incandescent, thereby emitting light. A gas prepared by introducing a halogen element (iodine, bromine and the like) in trace amounts into an inert gas such as nitrogen, argon and the like is sealed in the glass tube. The introduction of the halogen element allows the temperature of the filament to be set at a high temperature while suppressing a break in the filament. Thus, the halogen lamps HL have the properties of having a longer life than typical incandescent lamps and being capable of continuously emitting intense light. That is, the halogen lamps HL are continuous lighting lamps that emit light continuously for not less than one second. In addition, the halogen lamps HL, which are rod-shaped lamps, have a long life. The arrangement of the halogen lamps HL in a horizontal direction provides good efficiency of radiation toward the semiconductor wafer W provided over the halogen lamps HL.

A reflector 43 is provided also inside the enclosure 41 of the halogen heating part 4 under the halogen lamps HL arranged in two tiers (FIG. 1). The reflector 43 reflects the light emitted from the halogen lamps HL toward the heat treatment space 65.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a magnetic disk for storing control software, data and the like thereon. The CPU in the controller 3 executes a predetermined processing program, whereby the processes in the heat treatment apparatus 1 proceed.

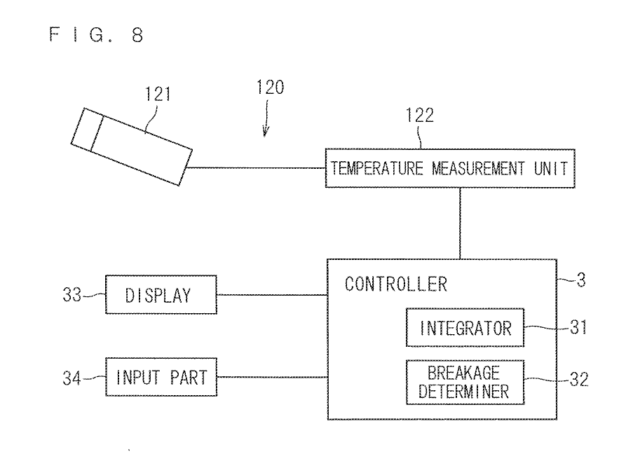

FIG. 8 is a block diagram showing functions of a radiation thermometer and a controller. The radiation thermometer 120 that measures the temperature of a lower surface of the semiconductor wafer W includes an infrared sensor 121 and a temperature measurement unit 122. The infrared sensor 121 receives infrared radiation emitted from the lower surface of the semiconductor wafer W held by the susceptor 74 through an opening 78. The infrared sensor 121 is electrically connected to the temperature measurement unit 122, and transmits a signal generated in response to light reception to the temperature measurement unit 122. The temperature measurement unit 122 includes an amplifier circuit, an A/D converter, a temperature conversion circuit, and the like (not shown) and converts a signal indicating the intensity of the infrared light output from the infrared sensor 121 into a temperature. The temperature acquired by the temperature measuring unit 122 is the temperature of the lower surface of the semiconductor wafer W.

The radiation thermometer 130 that measures the temperature of the susceptor 74 and the radiation thermometer 140 that measures the temperature of an upper surface of the semiconductor wafer W have substantially the same configuration as that of the radiation thermometer 120.

The radiation thermometer 120 is electrically connected to the controller 3 which is the controller of the entire heat treatment apparatus 1 and the temperature of the lower surface of the semiconductor wafer W measured by the radiation thermometer 120 is transmitted to the controller 3. The controller 3 includes an integrator 31 and a breakage determiner 32. The integrator 31 and the breakage determiner 32 are functional processing parts implemented by executing a predetermined processing program by the CPU of the controller 3. The processing of the integrator 31 and the processing of the breakage determiner 32 will be described later.

And, a display 33 and an input part 34 are connected to the controller 3. The controller 3 causes the display 33 to display various information thereon. The input part 34 is a device for an operator of the thermal processing apparatus 1 to input various commands and parameters to the controller 3. While confirming the display content of the display 33, the operator can also set conditions of processing recipes in which procedures and processing conditions of the semiconductor wafer W are described from the input unit 34. As the display 33 and the input part 34, a touch panel having both functions can also be used. In the preferred embodiment, a liquid crystal touch panel provided on the outer wall of the heat treatment apparatus 1 is adopted.

The heat treatment apparatus 1 further includes, in addition to the aforementioned components, various cooling structures to prevent an excessive temperature rise in the halogen heating part 4, the flash heating part 5, and the chamber 6 because of the heat energy generated from the halogen lamps HL and the flash lamps FL during the heat treatment of a semiconductor wafer W. As an example, a water cooling tube (not shown) is provided in the walls of the chamber 6. Also, the halogen heating part 4 and the flash heating part 5 have an air cooling structure for forming a gas flow therein to exhaust heat. Air is also supplied to the gap between the upper chamber window 63 and the lamp light radiation window 53 to cool the flash heating part 5 and the upper chamber window 63.

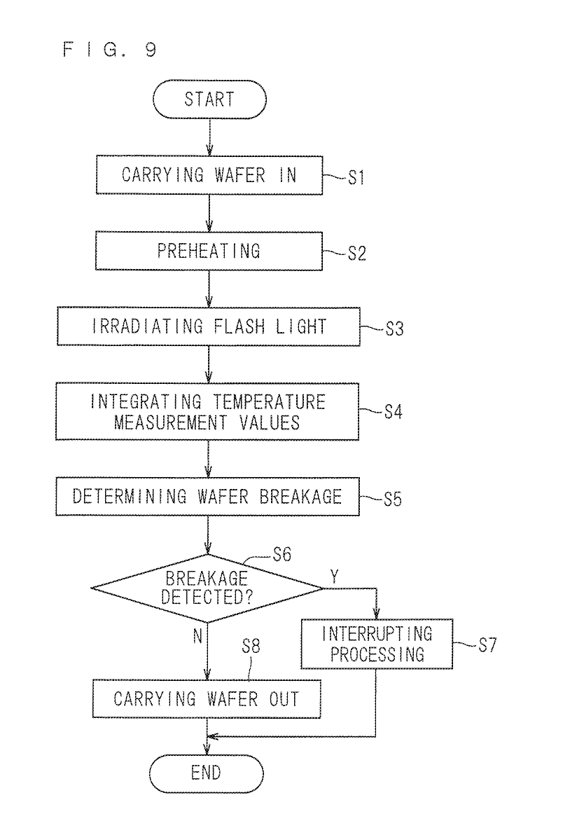

Next, a procedure for the treatment of a semiconductor wafer W in the heat treatment apparatus 1 will be described. FIG. 9 is a flowchart showing the procedure for the treatment of the semiconductor wafer W. A semiconductor wafer W to be treated herein is a semiconductor substrate doped with impurities (ions) by an ion implantation process. The impurities are activated by the heat treatment apparatus 1 performing the process of heating (annealing) the semiconductor wafer W by means of flash irradiation. The procedure for the treatment of the heat treatment apparatus 1 which will be described below proceeds under the control of the controller 3 over the operating mechanisms of the heat treatment apparatus 1.

First, the valve 84 is opened for supply of gas, and the valves 89 and 192 for exhaust of gas are opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

The gas within the chamber 6 is exhausted also through the transport opening 66 by opening the valve 192. Further, the exhaust mechanism not shown exhausts an atmosphere near the drivers of the transfer mechanism 10. It should be noted that the nitrogen gas is continuously supplied into the heat treatment space 65 during the heat treatment of a semiconductor wafer W in the heat treatment apparatus 1. The amount of nitrogen gas supplied into the heat treatment space 65 is changed as appropriate in accordance with process steps.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6 (step S1). At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held on the susceptor 74. The semiconductor wafer W is held by the holder 7 in such an attitude that the front surface thereof patterned and implanted with impurities is the upper surface. A predetermined distance is defined between the back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

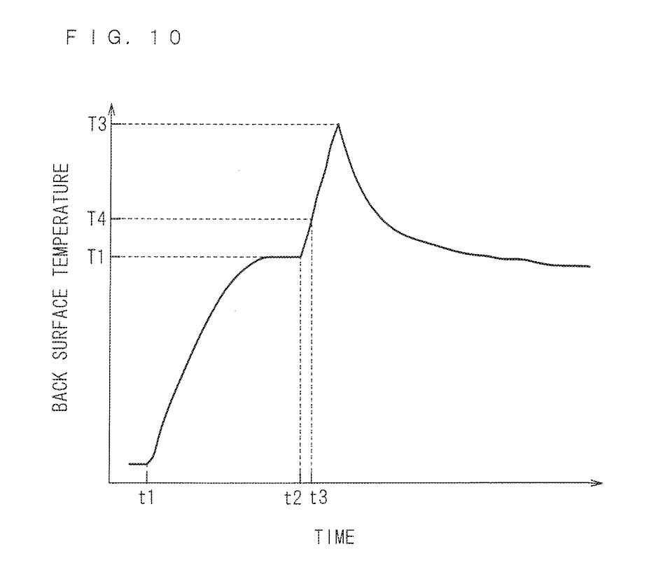

At the point when the semiconductor wafer W is supported from below in a horizontal attitude by the susceptor 74 of the holder 7 made of quartz, temperature measurement with the radiation thermometer 120 is started. Specifically, the radiation thermometer 120 receives infrared radiation emitted from the lower surface (back surface) of the semiconductor wafer W held by the susceptor 74 through the opening 78 to measure the temperature of the back surface of the semiconductor wafer W. FIG. 10 is a graph showing changes of the back surface temperature of the semiconductor wafer W measured by the radiation thermometer 120.

After the semiconductor wafer W is transported into the chamber 6 and held by the susceptor 74, at the time t1, the 40 halogen lamps HL in the halogen heating part 4 turn on simultaneously to start preheating (or assist-heating) (step S2). Halogen light emitted from the halogen lamps HL is transmitted through the lower chamber window 64 and the susceptor 74 both made of quartz, and impinges upon the lower surface of the semiconductor wafer W. By receiving light irradiation from the halogen lamps HL, the semiconductor wafer W is preheated, so that the temperature of the semiconductor wafer W increases. It should be noted that the transfer arms 11 of the transfer mechanism 10, which are retracted to the inside of the recessed portion 62, do not become an obstacle to the heating using the halogen lamps HL.

The temperature of the semiconductor wafer W which rises with light irradiation from the halogen lamps HL is measured with the radiation thermometer 120. The measured temperature of the semiconductor wafer W is transmitted to the controller 3. The controller 3 controls the output from the halogen lamps HL while monitoring whether the temperature of the semiconductor wafer W which is on the increase by the irradiation with light from the halogen lamps HL reaches a predetermined preheating temperature T1 or not. In other words, the controller 3 effects feedback control of the output from the halogen lamps HL so that the temperature of the semiconductor wafer W is equal to the preheating temperature T1, based on the value measured with the radiation thermometer 120. The preheating temperature T1 shall be on the order of 2000 to 800° C., preferably on the order of 350° to 600° C., (in the present preferred embodiment, 600° C.) at which there is no apprehension that the impurities implanted in the semiconductor wafer W are diffused by heat. As described above, the radiation thermometer 120 is a sensor for controlling the output of the halogen lamps HL in the preheating stage. Although the radiation thermometer 120 measures the temperature of the back surface of the semiconductor wafer W, no temperature difference occurs between the front surface and the back surface in the stage of the preheating using the halogen lamps HL, therefore, the back surface temperature measured by the radiation thermometer 120 is regarded as the temperature of the entire semiconductor wafer W.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured with the radiation thermometer 120 reaches the preheating temperature T1, the controller 3 adjusts the output from the halogen lamps HL to maintain the temperature of the semiconductor wafer W at approximately the preheating temperature T1.

By performing preheating with such halogen lamps HL, the temperature of the entire semiconductor wafer W is uniformly raised to the preheating temperature T1. In the preheating stage performed by the halogen lamps HL, the temperature of the peripheral portion of the semiconductor wafer W in which heat is more likely to be released, tends to be lower than the middle portion thereof, however, in the halogen heating part 4, the halogen lamps HL are disposed at a higher density in a region opposed to the middle portion of a substrate W than in a region opposed to the peripheral portion thereof. This allows a greater amount of light to impinge upon the peripheral portion of the semiconductor wafer W where the heat is likely to be released, thereby, uniformizing in-plane temperature distribution of the semiconductor wafer W in the preheating stage is ensured.

The flash lamps FL in the flash heating part 5 irradiate the front surface of the semiconductor wafer W held by the susceptor 74 with a flash of light at the time t2 when a predetermined time period has elapsed since the temperature of the semiconductor wafer W reached the preheating temperature TI (step S3). At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2 of 1000° C. or higher. After activation of the impurities implanted in the semiconductor wafer W are activated, the front surface temperature of the semiconductor wafer W decreases rapidly. Because of the capability of increasing and decreasing the front surface temperature of the semiconductor wafer W in an extremely short time, the heat treatment apparatus 1 achieves the activation of the impurities implanted in the semiconductor wafer W while suppressing the diffusion of the impurities due to heat. It should be noted that the time required for the activation of the impurities is extremely short as compared with the time required for the thermal diffusion of the impurities. Thus, the activation is completed in a short time ranging from about 0.1 to about 100 milliseconds during which no diffusion occurs.

Flash heating, in which the temperature of the front surface of the semiconductor wafer W is sharply increased by emitting flashes of light in an extremely short time, causes a temperature difference between the front surface and the back surface of the semiconductor wafer W. That is, the temperature of the front surface of the semiconductor wafer W on which the flashes of light are irradiated first increases and the temperature of the back surface later increases by heat conduction from the front surface.

The maximum temperature T3 to which the temperature of the back surface of the semiconductor wafer W reaches during flash heating is lower than the maximum temperature (treatment temperature T2) to which the temperature of the front surface reaches. Therefore, the temperature change of the back surface of the semiconductor wafer W during flash heating is gentler than the temperature change of the front surface thereof.

The temperature of the back surface of the semiconductor wafer W is measured by the radiation thermometer 120 even after the time t2 when the flash light irradiation is started. The sampling interval of the radiation thermometer 120 is, for example, 10 milliseconds. As described above, the irradiation time of flashes of light is extremely short; however, the temperature change of the back surface of the semiconductor wafer W during flash heating is gentle over a relatively long period, therefore, the back surface is capable of following such a temperature change even with the sampling interval of 10 milliseconds. And, the back surface of the semiconductor wafer W is measured at intervals of 10 milliseconds by the radiation thermometer 120 even after the time t2, thereby, acquiring such a temperature profile showing in FIG. 10.

In the preferred embodiment, of a plurality of temperature measurement values acquired by measurement, by the radiation thermometer 120, of the temperature of the back surface of the semiconductor wafer W at the sampling intervals of 10 milliseconds, the integrator 31 (FIG. 8) calculates a temperature integrated value by integrating the set number of temperature measurement values acquired after the time t3 which is a start point of integration (step S4). The time t3, which is the start point of integration, is a time point at which the temperature of the semiconductor wafer W reaches a trigger temperature T4 for starting integration in which the temperature of the semiconductor wafer W rises higher than the preheating temperature T1 by a set temperature ΔT during flash heating. Therefore, the start time of integration (time t3) comes after the start of flash light irradiation (time t2). The set temperature ΔT is a preset apparatus parameter of the heat treatment apparatus 1. The apparatus parameter is a parameter for control set for the controller 3 of the heat treatment apparatus 1. Setting 0° C. as the set temperature ΔT is also possible. When the set temperature ΔT is 0° C., the start point of integration coincides with the start time of flash light irradiation.

And, the integrator 31 integrates the set number N of the temperature measurement values acquired after the start point of integration. That is, the set number N is the number of temperature measurement values to be integrated. The set number N is also a preset apparatus parameter of the heat treatment apparatus 1. In the preferred embodiment, 300 is set as the set number N. Integration of 300 temperature measurement values acquired at sampling intervals of 10 milliseconds means to integrate the temperature measurement values of the semiconductor wafer W measured for 3 seconds from the start point of integration. In addition to the set temperature ΔT and the set number N, the sampling interval of the radiation thermometer 120 is also a value preset as an apparatus parameter.

The integration of the temperature measurement values by the integrator 31 is expressed by the following equation (1). In the equation (1), S represents a temperature integrated value, and T1 represents a temperature measurement value of the semiconductor wafer W by the radiation thermometer 120. Specifically, the integrator 31 obtains the temperature integrated value S by sequentially adding N (300 in the present embodiment) temperature measurement values after the start point of integration.

$$\begin{matrix}[ Expression 1 ] & \\ S = {\sum }_{i = 1}^{N} T i & ( 1 )\end{matrix}$$

Next, the breakage determiner 32 determines breakage of the semiconductor wafer W based on the temperature integrated value S (step S5). When the semiconductor wafer W is broken at the time of flash light irradiation, the temperature measurement by the radiation thermometer 120 is hindered, and an abnormal temperature measurement value is obtained. And, the temperature integrated value S obtained by integrating such abnormal temperature measurement values is also an abnormal value. Therefore, breakage of the semiconductor wafer W can be determined by determining whether the temperature integrated value S falls within an appropriate range. Specifically, the breakage determiner 32 determines breakage of the semiconductor wafer W based on the equation (2). In the equation (2), LL and UL represent the lower limit value and the upper limit value for breakage determination, respectively. The breakage determiner 32 determines that the semiconductor wafer W is not broken when the expression (2) is satisfied, and determines that the semiconductor wafer W is broken when the expression (2) is not satisfied. That is, the breakage determiner 32 determines that the semiconductor wafer W is broken when the temperature integrated value S falls out of the range between the predetermined upper limit value UL and the predetermined lower limit value LL.

[Expression 2]

LL<S<UL (2)

The upper limit value UL and the lower limit value LL are values that are set as recipe parameters, while the aforementioned set temperature ΔT, the set number N, and the sampling interval are set as the apparatus parameters. The recipe parameter is a parameter set in a processing recipe describing a procedure and a processing condition of the semiconductor wafer W. The processing recipe is passed to the controller 3 for each semiconductor wafer W to be processed, therefore, the recipe parameter can also be set for each semiconductor wafer W.

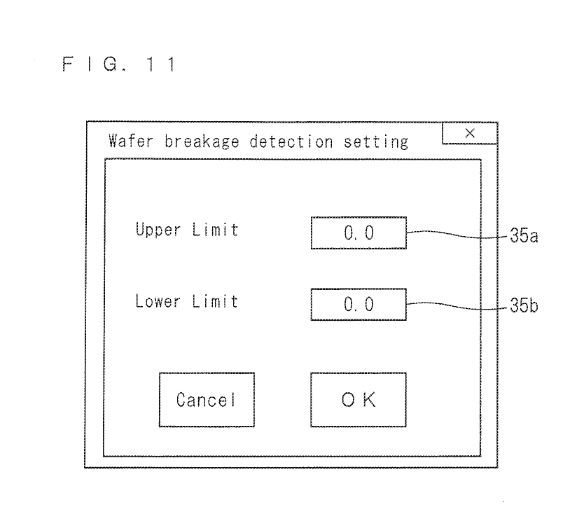

FIG. 11 is a diagram showing an example of a setting screen of an upper limit value UL and a lower limit value LL. The setting screen of FIG. 1 is a screen displayed on a touch panel of the controller 3 functioning as the display 33 and input part 34. The operator of the heat treatment apparatus 1 can perform setting by inputting a numerical value of the upper limit value UL from the text box 35a of the setting screen and inputting a numerical value of the lower limit value LL from the text box 35b as shown in FIG. 11. For example, when breakage does not occur, the temperature integrated value obtained by the expression (1) is treated as a standard value, and a value in which a predetermined threshold is added to the standard value and a value in which the predetermined threshold is subtracted from the standard value, are preferably adopted as the upper limit value UL and the lower limit value LL, respectively. The smaller the range between the upper limit value UL and the lower limit value LL is, the stricter the breakage determination is performed.

Referring again to FIG. 9, when the breakage determiner 32 determines that the semiconductor wafer W is broken after the start of flash light irradiation, the process proceeds from step S6 to step S7, the controller 3 interrupts the processing in the heat treatment apparatus 1 and the operation of the transportation system for transporting the semiconductor wafer W into and out of the chamber 6 is also stopped. Further, the controller 3 may issue a warning of occurrence of wafer breakage to the display 33. When breakage of the semiconductor wafer W occurs, particles are generated in the chamber 6, therefore, the chamber 6 is opened and cleaning work is performed.

Meanwhile, when the breakage determiner 32 determines that the semiconductor wafer W is not broken after the start of flash light irradiation, the process proceeds from step S6 to step S8, and a process for carrying out the semiconductor wafer W is performed. Specifically, after a predetermined time period has elapsed since the completion of the flash heating treatment, the halogen lamps HL turn off. This causes the temperature of the semiconductor wafer W to decrease rapidly from the preheating temperature TI. The radiation thermometer 120 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement with the radiation thermometer 120. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 to the outside. Thus, the heat treatment apparatus 1 completes the heating treatment of the semiconductor wafer W.

In the preferred embodiment, the radiation thermometer 120 measures the temperature of the back surface of the semiconductor wafer W at the sampling intervals of 10 milliseconds and acquires a plurality of temperature measurement values. Of a plurality of temperature measurement values, the integrator 31 integrates the set number N of the temperature measurement values acquired after the start point of integration and calculates the temperature integrated value S. The breakage determiner 32 determines breakage of the semiconductor wafer W after the start of flash light irradiation based on the temperature integrated value S. The radiation thermometer 120 is originally configured to control the output of the halogen lamp HL in the preheating stage. In other words, by using the radiation thermometer 120 for controlling the output of the halogen lamp HL also for breakage determination, the breakage of the semiconductor wafer W at the time of flash light irradiation can be detected with a simple configuration without adding a special hardware configuration to the heat treatment apparatus 1. In addition, breakage of the semiconductor wafer W is detected by a simple calculation process, this eliminates concern of lowering the throughput.

Further in the preferred embodiment, the temperature integrated value S is calculated by integrating the temperature measurement values obtained from the start point of integration after the start time of flash light irradiation. Therefore, when breakage of the semiconductor wafer W occurs during irradiation of flash light, abnormal temperature measurement values are integrated, therefore, the resulting temperature integrated value S is abnormal value, and this ensures accurate detection of breakage of the semiconductor wafer W.

### Second Embodiment

Next, the second embodiment of the present invention will be described. The configuration of the heat treatment apparatus 1 of the second embodiment is completely the same as that of the first embodiment. The processing procedure of the semiconductor wafer W in the heat treatment apparatus 1 of the second embodiment is also substantially the same as that of the first embodiment. The second embodiment is deferent from the first embodiment in that the temperature integrated value S for breakage determination is calculated by integrating temperature measurement values of the susceptor 74.

In the second embodiment, the radiation thermometer 130 measures the temperature of the middle part of the susceptor 74 at the predetermined sampling intervals (10 milliseconds, for example). Of a plurality of temperature measurement values acquired by measurement, by the radiation thermometer 130, of the temperature of the quartz susceptor 74 at the predetermined sampling intervals, the integrator 31 calculates a temperature integrated value S by integrating the set number N of temperature measurement values acquired from start point of integration after the start time of flash light irradiation. And, the breakage determiner 32 determines breakage of the semiconductor wafer W by determining whether the temperature integrated value S of the susceptor 74 falls within an appropriate range. The calculation processes for the breakage determination is the same as the equations (1) and (2) in the first embodiment.

Although the transparent susceptor 74 is hardly heated by light irradiation from the halogen lamp HL, the susceptor 74 is heated by heat conduction and thermal radiation from the heated semiconductor wafer W. Accordingly, when the semiconductor wafer W is broken at the time of flash light irradiation, heating of the susceptor 74 through the semiconductor wafer W is interrupted and the temperature change of the susceptor 74 also exhibits abnormal behavior. And, as a result of acquisition of abnormal temperature measurement values of the susceptor 74, a temperature integrated value S becomes an abnormal value accordingly. Therefore, breakage of the semiconductor wafer W can be determined by determining whether the temperature integrated value S of the susceptor 74 falls within an appropriate range.

<Modification>

While the preferred embodiment according to the present invention has been described hereinabove, various modifications of the present invention in addition to those described above may be made without departing from the scope and spirit of the invention. For example, breakage of the semiconductor wafer W is determined based on the temperature integrated value of the back surface of the semiconductor wafer W in the first embodiment and based on the temperature integrated value of the susceptor 74 in the second embodiment. However, breakage determination of the semiconductor wafer W may be performed based on a temperature integrated value obtained by integrating temperature measurement values other than the temperature integrated values described above. For example, breakage of the semiconductor wafer W may be determined based on a temperature integrated value obtained by integrating front surface temperatures of the semiconductor wafer W measured by the radiation thermometer 140. Alternatively, breakage of the semiconductor wafer W may be determined based on a temperature integrated value obtained by integrating ambient temperatures in the chamber 6 measured by the radiation thermometer 150. When the semiconductor wafer W is broken at time of flash light irradiation, the ambient temperature in the chamber 6 also exhibits an abnormal behavior due to the influence thereof, therefore, breakage determination can be performed based on the temperature integrated value of the ambient temperatures. That is, when the semiconductor wafer W is broken at the time of flash light irradiation, breakage determination for the semiconductor wafer W may be performed based on the temperature integrated value obtained by integrating the temperatures of elements exhibiting abnormal temperature change which is different from normal temperature change.

Also, “OR determination” may be performed between the breakage determination based on the temperature integrated value of the semiconductor wafer W in the first embodiment and the breakage determination based on the temperature integrated value of the susceptor 74 in the second embodiment. That is, the breakage determiner 32 may determine that the semiconductor wafer W is broken either when the temperature integrated value of the semiconductor wafer W is not within the appropriate range or when the temperature integrated value of the susceptor 74 is not within the appropriate range. Breakage determination of the semiconductor wafer W is more securely ensured with the above configuration. Alternatively, determination using other logical operations (for example, AND, XOR, etc.) may be performed between the breakage determination based on the temperature integrated value of the semiconductor wafer W and the breakage determination based on the temperature integrated value of the susceptor 74.

Although the 30 flash lamps FL are provided in the flash heating part 5 according to the aforementioned preferred embodiment, the present invention is not limited to this. Any number of flash lamps FL may be provided. The flash lamps FL are not limited to the xenon flash lamps, but may be krypton flash lamps. Also, the number of halogen lamps HL provided in the halogen heating part 4 is not limited to 40. Any number of halogen lamps HL may be provided.

In the aforementioned preferred embodiment, the filament-type halogen lamps HL are used as continuous lighting lamps that emit light continuously for not less than one second to preheat the semiconductor wafer W. The present invention, however, is not limited to this. In place of the halogen lamps HL, discharge type arc lamps (for example, xenon arc lamps) may be used as the continuous lighting lamps and preheating may be performed therewith.

Moreover, a substrate to be treated by the heat treatment apparatus 1 is not limited to a semiconductor wafer, but may be a glass substrate for use in a flat panel display for a liquid crystal display device and the like, and a substrate for a solar cell. Also, the technique according to the present invention may be applied to the heat treatment of high dielectric constant gate insulator films (high-k films), to the joining of metal and silicon, and to the crystallization of polysilicon.

While the invention has been described in detail, the foregoing description is in all aspects illustrative and not restrictive. It is understood that numerous other modifications and variations can be devised without departing from the scope of the invention.

What is claimed is:

1. A method of heating a substrate by irradiating the substrate with flash light, comprising the steps of:
(a) heating the substrate to a preheating temperature by irradiating with light from continuous lighting lamps;
(b) irradiating a front surface of said substrate with the flash light from a flash lamp;
(c) acquiring a plurality of temperature measurement values by measuring temperatures of said substrate at predetermined sampling intervals;
(d) of said plurality of temperature measurement values, calculating a temperature integrated value by integrating a set number of the temperature measurement values acquired from a start point of integration after a start time of irradiation of said flash light; and
(e) determining breakage of said substrate based on said temperature integrated value.

2. The method according to claim 1, wherein:
in said step (c), a temperature of a back surface of said substrate is measured.

3. A method of heating a substrate by irradiating the substrate with flash light, comprising the steps of:
(a) heating a substrate to a preheating temperature by irradiating said substrate held by a susceptor with light from continuous lighting lamps;
(b) irradiating a front surface of said substrate with the flash light from a flash lamp;
(c) acquiring a plurality of temperature measurement values by measuring temperatures of said susceptor at predetermined sampling intervals;
(d) of said plurality of temperature measurement values, calculating a temperature integrated value by integrating a set number of the temperature measurement values acquired from the start point of integration after a start time of irradiation of said flash light; and
(e) determining breakage of said substrate based on said temperature integrated value.

4. The method according to claim 1, wherein:
in said step (e), said substrate is determined to be broken when said temperature integrated value falls outside a range between an upper limit value and a lower limit value previously set.

5. The method according to claim 4, further comprising the step of
(f) setting said upper limit value and said lower limit value.

6. The method according to claim 1, wherein:
said start point of integration is a time point at which a temperature of said substrate rises higher than said preheating temperature by a set temperature.

7. A heat treatment apparatus for heating the substrate by irradiating the substrate with a flash of light, comprising:
a chamber for receiving a substrate therein;
a susceptor for holding the substrate in said chamber;
continuous lighting lamps for heating said substrate to a preheating temperature by irradiating said substrate held by said susceptor with light;
a flash lamp for irradiating a front surface of said substrate with the flash light;
a radiation thermometer for acquiring a plurality of temperature measurement values by measuring temperatures of said substrate at predetermined sampling intervals;
an integrator for, of said plurality of temperature measurement values, calculating a temperature integrated value by integrating a set number of the temperature measurement values acquired from the start point of integration after a start time of irradiation of said flash light; and
a determiner for determining breakage of said substrate based on said temperature integrated value.

8. The heat treatment apparatus according to claim 7, wherein:
said radiation thermometer measures a temperature of a back surface of said substrate.

9. A heat treatment apparatus for heating the substrate by irradiating the substrate with a flash of light, comprising:
a chamber for receiving a substrate therein;
a susceptor for holding the substrate in said chamber;
continuous lighting lamps for heating said substrate to a preheating temperature by irradiating said substrate held by said susceptor with light;
a flash lamp for irradiating a front surface of said substrate with the flash light;
a radiation thermometer for acquiring a plurality of temperature measurement values by measuring temperatures of said susceptor at predetermined sampling intervals;
an integrator for, of said plurality of temperature measurement values, calculating a temperature integrated value by integrating a set number of the temperature measurement values acquired from the start point of integration after a start time of irradiation of said flash light; and
a determiner for determining breakage of said substrate based on said temperature integrated value.

10. The heat treatment apparatus according to claim 7, wherein:
said determiner determines that said substrate is broken when said temperature integrated value falls outside a range between an upper limit value and a lower limit value previously set.

11. The heat treatment apparatus according to claim 10, further comprising
a setting unit for setting said upper limit value and said lower limit value.

12. The heat treatment apparatus according to claim 7, wherein:
said start point of integration is a time point at which a temperature of said substrate rises higher than said preheating temperature by a set temperature.
